(19) United States
(12) Patent Application Publication
(10) Pub. No.: US 2009/0160562 A1
(43) Pub. Date: Jun. 25, 2009

(54) OSCILLATING DEVICE

(76) Inventor: Hsien-Sheng Huang, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 12/193,042

(22) Filed: Aug. 17, 2008

(30) Foreign Application Priority Data
Dec. 19, 2007 (TW) 096148627

(51) Int. Cl. H03L 1/00; H03B 5/12; H03K 3/03

(52) U.S. Cl. 331/57; 331/176; 331/108 R

(57) ABSTRACT

The present invention provides an oscillating device. The oscillating device includes: a voltage regulating module, a current generating module, and an oscillating module. The voltage regulating module is utilized for generating a control voltage at an output terminal, and the voltage regulating module includes: a first operational amplifier, a first switch element, and a first voltage dividing circuit. The oscillating module includes: a plurality of switch modules connected in series, a current mirror module, and a plurality of capacitor modules. In the oscillating device of the present invention, a frequency of an oscillating signal outputted by the oscillating module will not be affected by voltage offset of an operating voltage, environment temperature variations, or semiconductor process variations.

### BACKGROUND OF THE INVENTION

1. Field of the Invention

The present invention relates to an oscillating device, and more particularly, to an oscillating device which can let a frequency of an oscillating signal outputted by the oscillating device not be affected by voltage offset of an operating voltage, environment temperature variations, or semiconductor process variations

2. Description of the Prior Art

In general, a frequency of an oscillating signal outputted by an oscillator of the prior art usually tends to be affected by voltage offset of an operating voltage, environment temperature variations, or semiconductor process variations. Thus, performance of the oscillator of the prior art is quite sensitive to the variations of the external environment, and the frequency of the oscillating signal outputted by the oscillator of the prior art usually has a problem of instability.

### SUMMARY OF THE INVENTION

It is therefore one of the objectives of the present invention to provide an oscillating device which can let a frequency of an oscillating signal outputted by the oscillating device not be affected by voltage offset of an operating voltage, environment temperature variations, or semiconductor process variations, so as to solve the above problem.

In accordance with an embodiment of the present invention, an oscillating device is disclosed. The oscillating device includes: a voltage regulating module, a current generating module, and an oscillating module. The voltage regulating module is utilized for generating a control voltage at an output terminal, and the voltage regulating module includes: a first operational amplifier, a first switch element, and a first voltage dividing circuit. The first operational amplifier has a first input terminal coupled to an operational voltage, a second input terminal, and an output terminal, and the first operational amplifier is coupled to a first voltage source. The first switch element has a control terminal coupled to the output terminal of the first operational amplifier, a first terminal coupled to the first voltage source, and a second terminal coupled to the second input terminal of the first operational amplifier. The first voltage dividing circuit is coupled between the first switch element and a second voltage source, and the first voltage dividing circuit includes a first voltage dividing element and a second voltage dividing element. The first voltage dividing element is coupled to the second input terminal and the output terminal of the first operational amplifier, and the second voltage dividing element is coupled between the output terminal and the second voltage source. In addition, the current generating module is coupled to the output terminal of the voltage regulating module, and utilized for generating a reference current according to the control voltage. The oscillating module is coupled between the voltage regulating module and the current generating module, and utilized for outputting an oscillating signal according to the reference current and the control voltage.

In accordance with an embodiment of the present invention, an oscillating device is disclosed. The oscillating device includes: a voltage regulating module, a current generating module, and a ring oscillator. The voltage regulating module is utilized for generating a control voltage at an output terminal. The current generating module is coupled to the output terminal of the voltage regulating module, and utilized for generating a reference current according to the control voltage. The ring oscillator is coupled between the voltage regulating module and the current generating module, and utilized for outputting an oscillating signal according to the reference current and the control voltage. The ring oscillator includes: a plurality of switch modules connected in serial, a current mirror module, and a plurality of capacitor modules. The current mirror module is coupled to the control voltage, the plurality of switch modules, and the current generating module, for respectively providing a current mirror current to the plurality of switch modules according to the reference current. Each of the plurality of capacitor modules is coupled between adjacent two switch modules in the plurality of switch modules, and each capacitor module is made up by at least a transistor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a simplified block diagram of an oscillating device in accordance with an exemplary embodiment of the present invention.

FIG. 2 shows a simplified circuit configuration diagram of the voltage regulating module shown in FIG. 1 in accordance with an exemplary embodiment.

FIG. 3 shows a simplified circuit configuration diagram of the current generating module shown in FIG. 1 in accordance with an exemplary embodiment.

FIG. 4 shows a simplified circuit configuration diagram of the oscillating module shown in FIG. 1 in accordance with an exemplary embodiment.

### DETAILED DESCRIPTION

Certain terms are used throughout the following description and the claims to refer to particular system components. As one skilled in the art will appreciate, manufacturers may refer to a component by different names. This document does not intend to distinguish between components that differ in name but not function. In the following discussion and in the claims, the terms “include”, “including”, “comprise”, and “comprising” are used in an open-ended fashion, and thus should be interpreted to mean “including, but not limited to . . . ” The terms “couple” and “coupled” are intended to mean either an indirect or a direct electrical connection. Thus, if a first device couples to a second device, that connection may be through a direct electrical connection, or through an indirect electrical connection via other devices and connections.

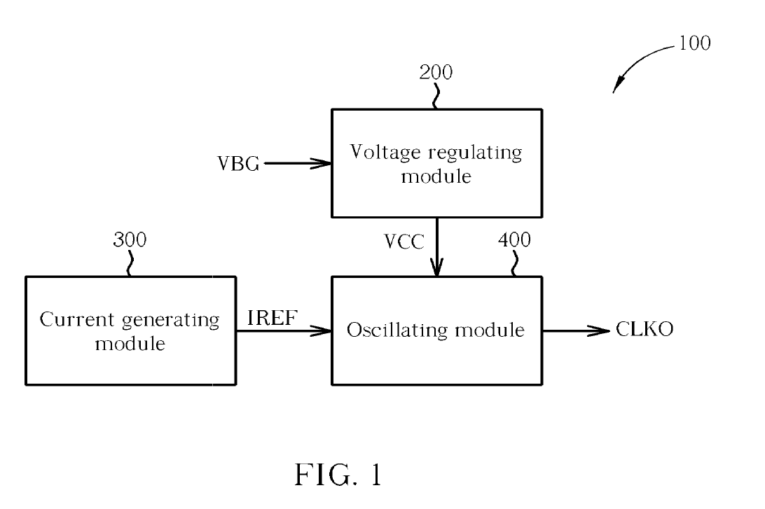

Please refer to FIG. 1. FIG. 1 shows a simplified block diagram of an oscillating device 100 in accordance with an exemplary embodiment of the present invention. As shown in FIG. 1, the oscillating device 100 includes: a voltage regulating module 200, a current generating module 300, and an oscillating module 400. The voltage regulating module 200 is utilized for generating a control voltage VCC. The current generating module 300 is coupled to the voltage regulating module 200, and utilized for generating a reference current IREF according to the control voltage VCC. The oscillating module 400 is coupled between the voltage regulating module 200 and the current generating module 300, and utilized for outputting an oscillating signal CLKO according to the reference current IREF and the control voltage VCC. Next, this document will illustrate the details of the circuit configuration and the operational scheme of the voltage regulating module 200, the current generating module 300, and the oscillating module 400 in the oscillating device 100 of the present invention.

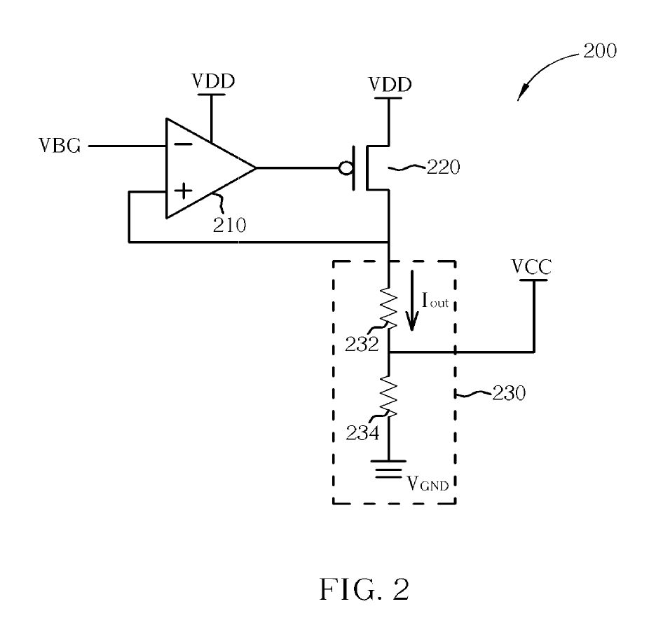

Please refer to FIG. 2. FIG. 2 shows a simplified circuit configuration diagram of the voltage regulating module 200 shown in FIG. 1 in accordance with an exemplary embodiment. As shown in FIG. 2, the voltage regulating module 200 includes: a first operational amplifier 210, a first switch element 220, and a first voltage dividing circuit 230. The first operational amplifier 210 has a first input terminal coupled to an operational voltage VBG, a second input terminal, and an output terminal, and the first operational amplifier 210 is coupled to a first voltage source VDD. In addition, the first switch element 220 is a P-type field effect transistor (FET) (such as a PMOSFET) in the circuit configuration diagram of this embodiment, and the first switch element 220 has a control terminal (i.e., a gate terminal) coupled to the output terminal of the first operational amplifier 210, a first terminal (i.e., a source terminal) coupled to the first voltage source VDD, and a second terminal (i.e., a drain terminal) coupled to the second input terminal of the first operational amplifier 210. The first voltage dividing circuit 230 is coupled between the first switch element 220 and a second voltage source VGND (i.e., a ground voltage source), and the first voltage dividing circuit 230 includes a first voltage dividing element 232 and a second voltage dividing element 234. The first voltage dividing element 232 is coupled to the second input terminal and an output terminal of the first operational amplifier 210, and the second voltage dividing element 234 is coupled between the output terminal of the voltage regulating module 200 and the second voltage source VGND. In this way, if a resistance value of the first voltage dividing element 232 is presumed to be Rvcc, a current value of a current passing through the first voltage dividing element 232 in the voltage regulating module 200 is lout, a voltage value of the control voltage VCC is Vc, and a voltage value of the operational voltage VBG is Vb, then a formula (1) can be obtained below:

Vc=Vb−Iout*Rvcc (1)

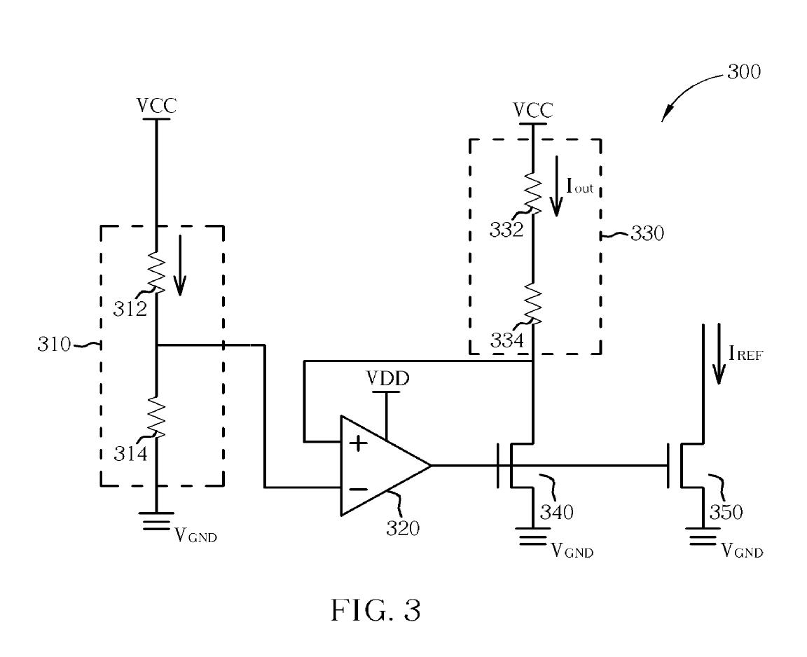

Please refer to FIG. 3. FIG. 3 shows a simplified circuit configuration diagram of the current generating module 300 shown in FIG. 1 in accordance with an exemplary embodiment. As shown in FIG. 3, the current generating module 300 includes: a second voltage dividing circuit 310, a second operational amplifier 320, an impedance module 330, a second switch element 340, and a third switch element 350. The second voltage dividing circuit 310 is coupled between the control voltage VCC and the second voltage source VGND, and utilized for generating a voltage level between the control voltage VCC and the second voltage source VGND. In this embodiment, a ratio of a resistance value of a first voltage dividing element 312 to a resistance value of a second voltage dividing element 314 in the second voltage dividing circuit 310 is 1:1, and thus the voltage level generated by the second voltage dividing circuit 310 is half the control voltage VCC (i.e., Vc/2). In addition, the second operational amplifier 320 has a first input terminal coupled to the second voltage dividing circuit 310, a second input terminal, and an output terminal. The second operational amplifier 320 is coupled to the first voltage source VDD, and the impedance module 330 is coupled between the control voltage VCC and the second input terminal of the second operational amplifier 320. In this embodiment, a first impedance element 332 and a second impedance element 334 in the impedance module 330 are a diffusion resistor and a polysilicon resistor, respectively, wherein the diffusion resistor and the polysilicon resistor have different temperature coefficients. Resistance values of the first impedance element 332 and the second impedance element 334 are Rd and Rp, respectively. In addition, in the circuit configuration diagram of this embodiment, the second switch element 340 and the third switch element 350 are both N-type FETs (such as an NMOSFET). The second switch element 340 has a control terminal (i.e., a gate terminal) coupled to the output terminal of the second operational amplifier 320, a first terminal (i.e., a source terminal) coupled to the second voltage source VGND, and a second terminal (i.e., a drain terminal) coupled to the second input terminal of the second operational amplifier 320. The third switch element 350 has a control terminal (i.e., a gate terminal) coupled to the output terminal of the second operational amplifier 320, a first terminal (i.e., a source terminal) coupled to the second voltage source VGND, and a second terminal (i.e., a drain terminal), wherein the second terminal is coupled to the oscillating module 400 and outputs the reference current IREF. In this way, if a current value of the reference current IREF is presumed to be Ir, then a formula (2) can be obtained below:

Iout=A*Ir=A*Vc/2(Rd+Rp) (2) (A is a constant)

A formula (3) can be obtained in accordance with the formula (1) and the formula (2) below:

Iout(Rvcc+2(Rd+Rp)/A)=Vb (3)

In addition, since a frequency of the oscillating signal CLKO outputted by the oscillating module 400 is directly proportional to the current value Ir of the reference current IREF, and is inversely proportional to ΔV of the oscillating module 400 (this part is well known to those of average skill in this art, and thus further explanation of the details and operations are omitted herein for the sake of brevity), the frequency of the oscillating signal CLKO outputted by the oscillating module 400 will not be affected when there is offset for the voltage value Vb of the operational voltage VBG. For example, when the voltage value Vb of the operational voltage VBG drops down, the current value Ir of the reference current IREF will drop down and result in the frequency of the oscillating signal CLKO going down. In the mean time, however, since the dropping down of the current value Ir of the reference current IREF will result in the voltage value Vc of the control voltage VCC also dropping down (i.e., ΔV also drops down), the frequency of the oscillating signal CLKO will rise, and a compensation effect can be formed in this way. Thus, the frequency of the oscillating signal CLKO outputted by the oscillating module 400 will not be affected by the offset of the voltage value Vb of the operational voltage VBG.

In addition, in the oscillating device disclosed in the present invention, a temperature coefficient of the reference current IREF can be determined via properly selecting a ratio between the resistance value Rd of the first impedance element 332 and the resistance value Rp of the second impedance element 334 and selecting a temperature parameter of the operational voltage VBG. Thus, the frequency of the oscillating signal CLKO outputted by the oscillating module 400 will not be affected by the environment temperature variations in this way.

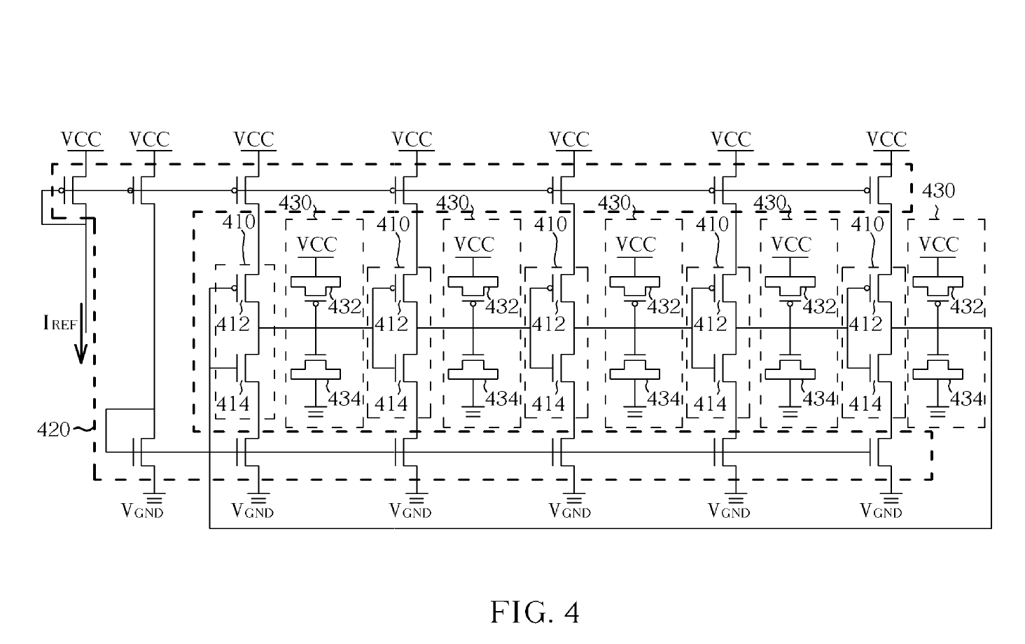

Please refer to FIG. 4. FIG. 4 shows a simplified circuit configuration diagram of the oscillating module 400 shown in FIG. 1 in accordance with an exemplary embodiment. As shown in FIG. 4, the oscillating module 400 includes: five switch modules 410 connected in series, a current mirror module 420, and five capacitor modules 430. The current mirror module 420 is coupled to the control voltage VCC, the five switch modules 410, and the current generating module 300. The current mirror module 420 is utilized for respectively providing a current mirror current (i.e., the reference current IREF) to each of the five switch modules 410 according to the reference current IREF. Each of the five capacitor modules 430 is coupled between adjacent two switch modules 410 in the five switch modules 410. In this embodiment, each switch module 410 is an inverter, and includes a P-type FET 412 (such as a PMOSFET) and an N-type FET 414 (such as an NMOSFET). Each capacitor module 430 includes: a first capacitor made up by a P-type FET 432 (such as a PMOSFET), and a second capacitor made up by an N-type FET 434 (such as an NMOSFET). The control terminals (i.e., gate terminals) of the P-type FET 432 and the N-type FET 434 are coupled to an output terminal of an inverter (i.e., a switch module 410) and an input terminal of another inverter adjacent to the inverter. A first terminal (i.e., a source terminal) and a second terminal (i.e., a drain terminal) of the P-type FET 432 are coupled to the control voltage VCC. A first terminal (i.e., a source terminal) and a second terminal (i.e., a drain terminal) of the N-type FET 434 are coupled to the second voltage source VGND. In addition, please note that all the FETs in the oscillating module 400 are fabricated by the same semiconductor process, and thus the frequency of the oscillating signal CLKO outputted by the oscillating module 400 will not be affected by the semiconductor process variations after the present invention adds the capacitor modules 430 coupled between adjacent two switch modules 410 in the five switch modules 410. For example, when thicknesses of the gate oxide layers of the P-type FETs 412 in the switch modules 410 decrease, threshold voltages of the P-type FETs 412 will also decrease, and enhance the driving ability. In the mean time, however, since thicknesses of the gate oxide layers of the P-type FETs 432 in the capacitor modules 430 will also decrease, capacitance values of the capacitor modules 430 will increase. Thus, the frequency of the oscillating signal CLKO outputted by the oscillating module 400 will not be affected by the semiconductor process variations in this way. In addition, please note that the above embodiments are only for illustrative purposes and are not meant to be limitations of the present invention.

Briefly summarized, in the oscillating device 100 disclosed in the present invention, the frequency of the oscillating signal CLKO outputted by the oscillating module 400 will not be affected by the offset of the voltage value Vb of the operational voltage VBG, the environment temperature variations, or the semiconductor process variations.

Those skilled in the art will readily observe that numerous modifications and alterations of the device and method may be made while retaining the teachings of the invention.

What is claimed is:

1. An oscillating device, comprising:
a voltage regulating module, for generating a control voltage at an output terminal, comprising:
a first operational amplifier, having a first input terminal coupled to an operational voltage, a second input terminal, and an output terminal, the first operational amplifier being coupled to a first voltage source;
a first switch element, having a control terminal coupled to the output terminal of the first operational amplifier, a first terminal coupled to the first voltage source, and a second terminal coupled to the second input terminal of the first operational amplifier; and
a first voltage dividing circuit, coupled between the first switch element and a second voltage source, comprising:
a first voltage dividing element, coupled to the second input terminal and the output terminal of the first operational amplifier; and
a second voltage dividing element, coupled between the output terminal of the voltage regulating module and the second voltage source;
a current generating module, coupled to the output terminal of the voltage regulating module, for generating a reference current according to the control voltage; and
an oscillating module, coupled between the voltage regulating module and the current generating module, for outputting an oscillating signal according to the reference current and the control voltage.

2. The oscillating device of claim 1, wherein the current generating module comprises:
a second voltage dividing circuit, coupled between the control voltage and the second voltage source, for generating a voltage level between the control voltage and the second voltage source;
a second operational amplifier, having a first input terminal coupled to the second voltage dividing circuit, a second input terminal, and an output terminal, the second operational amplifier being coupled to the first voltage source;
an impedance module, coupled between the control voltage and the second input terminal of the second operational amplifier;
a second switch element, having a control terminal coupled to the output terminal of the second operational amplifier, a first terminal coupled to the second voltage source, and a second terminal coupled to the second input terminal of the second operational amplifier; and
a third switch element, having a control terminal coupled to the output terminal of the second operational amplifier, a first terminal coupled to the second voltage source, and a second terminal, wherein the second terminal is coupled to the oscillating module and outputs the reference current.

3. The oscillating device of claim 2, wherein the impedance module comprises a diffusion resistor connected to a polysilicon resistor in series, and the diffusion resistor and the polysilicon resistor have different temperature coefficients.

4. The oscillating device of claim 2, wherein the second switch element and the third switch element are transistors.

5. The oscillating device of claim 4, wherein the second switch element and the third switch element are N type field effect transistors (FETs).

6. The oscillating device of claim 1, wherein the oscillating module is a ring oscillator, comprising:
a plurality of switch modules connected in series;
a current mirror module, coupled to the control voltage, the plurality of switch modules, and the current generating module, for respectively providing a current mirror current to the plurality of switch modules according to the reference current; and
a plurality of capacitor modules, each coupled between adjacent two switch modules in the plurality of switch modules and being made up by at least a transistor.

7. The oscillating device of claim 6, wherein each switch module is an inverter comprising a first transistor and a second transistor; each capacitor module comprises a first capacitor made up by a third transistor and a second capacitor made up by a fourth transistor, and control terminals of the third transistor and the fourth transistor are coupled to an output terminal of an inverter and an input terminal of another inverter adjacent to the inverter; a first terminal and a second terminal of the third transistor are coupled to the control voltage; and a first terminal and a second terminal of the fourth transistor are coupled to the second voltage source.

8. An oscillating device, comprising:
a voltage regulating module, for generating a control voltage at an output terminal;
a current generating module, coupled to the output terminal of the voltage regulating module, for generating a reference current according to the control voltage; and
a ring oscillator, coupled between the voltage regulating module and the current generating module, for outputting an oscillating signal according to the reference current and the control voltage, the ring oscillator comprising:
a plurality of switch modules connected in series;
a current mirror module, coupled to the control voltage, the plurality of switch modules, and the current generating module, for respectively providing a current mirror current to the plurality of switch modules according to the reference current; and
a plurality of capacitor modules, each coupled between adjacent two switch modules in the plurality of switch modules and being made up by at least a transistor.

9. The oscillating device of claim 8, wherein each switch module is an inverter comprising a first transistor and a second transistor; each capacitor module comprises a first capacitor made up by a third transistor and a second capacitor made up by a fourth transistor, control terminals of the third transistor and the fourth transistor are coupled to an output terminal of an inverter and an input terminal of another inverter adjacent to the inverter; a first terminal and a second terminal of the third transistor are coupled to the control voltage; and a first terminal and a second terminal of the fourth transistor are coupled to the second voltage source.

10. The oscillating device of claim 8, wherein the current generating module comprises:
a second voltage dividing circuit, coupled between the control voltage and the second voltage source, for generating a voltage level between the control voltage and the second voltage source;
a second operational amplifier, having a first input terminal coupled to the second voltage dividing circuit, a second input terminal, and an output terminal, the second operational amplifier being coupled to the first voltage source;
an impedance module, coupled between the control voltage and the second input terminal of the second operational amplifier;
a second switch element, having a control terminal coupled to the output terminal of the second operational amplifier, a first terminal coupled to the second voltage source, and a second terminal coupled to the second input terminal of the second operational amplifier; and
a third switch element, having a control terminal coupled to the output terminal of the second operational amplifier, a first terminal coupled to the second voltage source, and a second terminal, wherein the second terminal is coupled to the oscillating module and outputs the reference current.

11. The oscillating device of claim 10, wherein the impedance module comprises a diffusion resistor connected to a polysilicon resistor in series, and the diffusion resistor and the polysilicon resistor have different temperature coefficients.

12. The oscillating device of claim 10, wherein the second switch element and the third switch element are transistors.

13. The oscillating device of claim 12, wherein the second switch element and the third switch element are N type FETs.
